(19) United States
(12) Patent Application Publication
(10) Pub. No.: US 2003/0037960 A1
(43) Pub. Date: Feb. 27, 2003

(54) Layered circuit boards and methods of production thereof

(76) Inventor: Stephen S. Ohr, Chippewa Falls, WI (US)

Correspondence Address: Honeywell International Inc., Law Dept. AB2, 101 Columbia Road, P.O. Box 2245, Morristown, NJ, 07962, US

(21) Appl. No.: 09/940,278

(22) Filed: Aug. 27, 2001

(51) Int. Cl. H05K 1/16; H05K 3/02

(52) U.S. Cl. 174/260; 29/846; 29/847

(57) ABSTRACT

Compositions and methods are provided whereby layered materials, electronic components and electronic products may be produced comprising a) a substrate layer; b) an active component layer that comprises an active material coupled to an adhesion promoter layer, wherein the adhesive promoter layer is selectively patterned to expose a contact area on the active material; and c) at least one additional layer. A method of producing these layered materials comprises a) providing an active material layer; b) forming an active component layer by applying an adhesion promoter layer to the active material layer; c) coating the active component layer with a photoresist material; d) patterningly exposing a portion of the photoresist material; e) removing the unexposed photoresist material from the active component layer to form a bare active component layer comprising the active material and the adhesion promoter layer and a covered active component layer comprising the active material, the adhesion promoter and the photoresist material; f) contacting the bare active component layer with a reactive solution, wherein the reactive solution removes the adhesion promoter layer from the bare active component layer to form a contact area; and g) removing any remaining photoresist material from the active component layer.

### FIELD OF THE INVENTION

The field of the invention is electronic components.

### BACKGROUND OF THE INVENTION

Electronic components are used in ever increasing numbers of consumer and commercial electronic products. Examples of some of these consumer and commercial products are televisions, computers, cell phones, pagers, a Palm-type organizer, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging.

Components, therefore, are being broken down and investigated to determine if there are better building materials and methods that will allow them to be scaled down to accommodate the demands for smaller electronic components. In layered components, one goal appears to be decreasing the number or the size of the layers. This task can be difficult, however, given that several of the layers and components of the layers should generally be present in order to operate the component.

In order to maximize the efficiency of scaled down layered materials and component, individual layers within components should then be tested as the layered component and/or material is assembled. Also, problems with the component or material must be diagnosed with greater accuracy than conventional methods currently allow, in order to reduce the effects of compounding multiple electrical defects and inefficiencies in a layered structure within an electronic component or electronic product and to continually monitor the performance of the component and the layers within the component.

Thus, there is a continuing need to a) design and produce layered materials that meet customer specifications while minimizing the size and number of layers, and b) develop reliable and accurate methods of producing and testing desired layered materials and components comprising those layered materials.

### SUMMARY OF THE INVENTION

Layered materials, electronic components and electronic products may be produced that comprise a) a substrate layer; b) an active component layer that comprises an active material coupled to an adhesion promoter layer, wherein the adhesive promoter layer is selectively patterned to expose a contact area on the active material; and c) at least one additional layer.

A contemplated method of producing desirable layered materials comprises a) providing an active material layer; b) forming an active component layer by applying an adhesion promoter layer to the active material layer; c) coating the active component layer with a photoresist material; d) patterningly exposing a portion of the photoresist material; e) removing the unexposed photoresist material from the active component layer to form a bare active component layer comprising the active material and the adhesion promoter layer and a covered active component layer comprising the active material, the adhesion promoter and the photoresist material; f) contacting the bare active component layer with a reactive solution, wherein the reactive solution removes the adhesion promoter layer from the bare active component layer; and g) removing any remaining photoresist material from the active component layer.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a schematic diagram of a conventional layered arrangement.

FIG. 2 is a schematic diagram of a conventional layered arrangement.

FIG. 3 is a flowchart showing a preferred embodiment of the method of the contemplated invention.

FIG. 4 is a schematic diagram of a preferred embodiment.

FIG. 5 is a schematic diagram of a preferred embodiment.

### DETAILED DESCRIPTION

Electronic components, as contemplated herein, are generally thought to comprise any layered component that can be utilized in an electronic-based product. Contemplated electronic components comprise circuit boards, chip packaging, separator sheets, dielectric components of circuit boards, printed-wiring boards, and other components of circuit boards, such as capacitors, inductors, and resistors.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

Electronic products and components may comprise layered materials, layered components, and components that are laminated in preparation for use in the component or product.

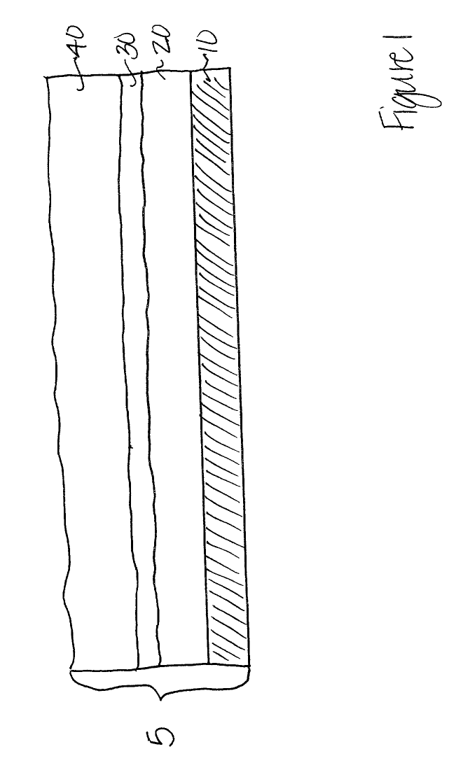

FIG. 1 shows a layered structure 5 that may be part of a multi-layered printed circuit board assembly. The layered structure 5 generally comprises a) a substrate 10; b) a first layer 20 of active material; c) a second layer 30 comprising an adhesion promoter; and d) at least one additional layer 40 of material, such as an adhesive layer, another layer of active material, a dielectric layer or a laminate layer.

The first layer 20 of a layered structure 5 is generally contemplated to comprise a resistor, a capacitor, a signal layer or some other electrically active layer. Therefore, the active material that makes up the first layer 20 may comprise that material or combination of materials necessary to produce the first layer 20, such as resistor paste, capacitor paste, metals, metal alloys, composite materials, or conductive polymers.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, zinc, vanadium, aluminum, chromium, platinum, gold, silver, tungsten, molybdenum, cerium, promethium, and thorium. More preferred metals include titanium, silicon, copper, nickel, platinum, gold, silver and tungsten. Most preferred metals include titanium, silicon, copper and nickel. The term “metal” also includes alloys, metal/metal composites, metal ceramic composites, metal polymer composites, as well as other metal composites.

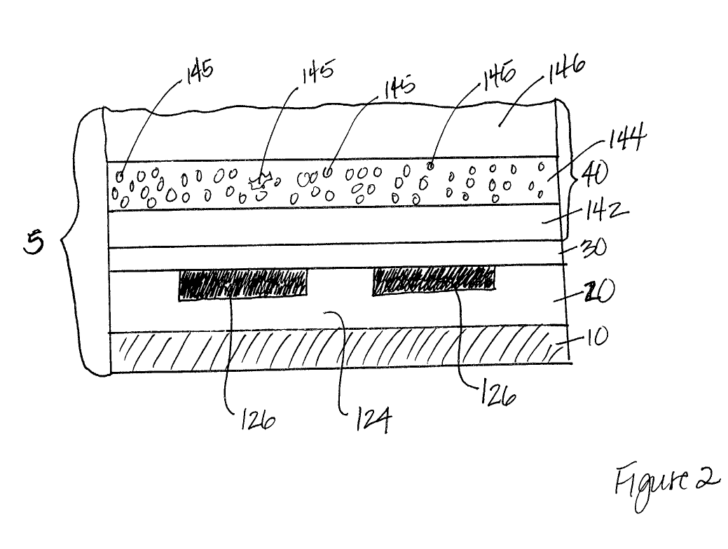

FIG. 2 shows another layered structure 5 that could be a component of an electronic product or a printed circuit board that comprises a) a substrate layer 10; b) a first layer 20, wherein the first layer comprises an insulating material 124 and an active material 126 embedded within or otherwise coupled to the insulating material 124; c) a second layer 30, wherein the second layer 30 comprises an adhesion promoter material; and d) at least one additional layer 40, wherein the at least one additional layer 40 comprises an adhesive layer 142, a porous layer 144 having a plurality of voids 145, and a non-porous layer 146.

One common problem with the construction of the layered structures in FIGS. 1 and 2 is that it is difficult to reliably and accurately measure the electrical signal coming from the active material after the adhesion promoter layer has been applied, which is usually at the end of the first print cycle. A “print cycle” is a subset of machinery commands that are part of a predetermined set of “print cycles”, otherwise characterized as a full set of machinery commands, designed to produce a printed circuit board or layered structure and that are initially programmed into the printing machinery and instruments. The adhesion promoter layer acts as an insulator layer between the electrical probe or testing apparatus and the active material and effectively prohibits accurate and reliable electrical measurements of the underlying active material.

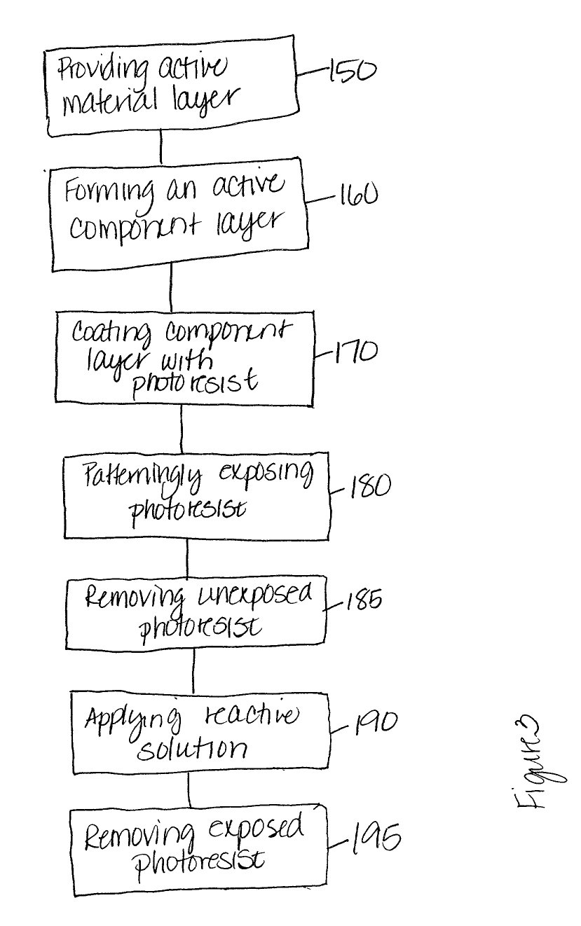

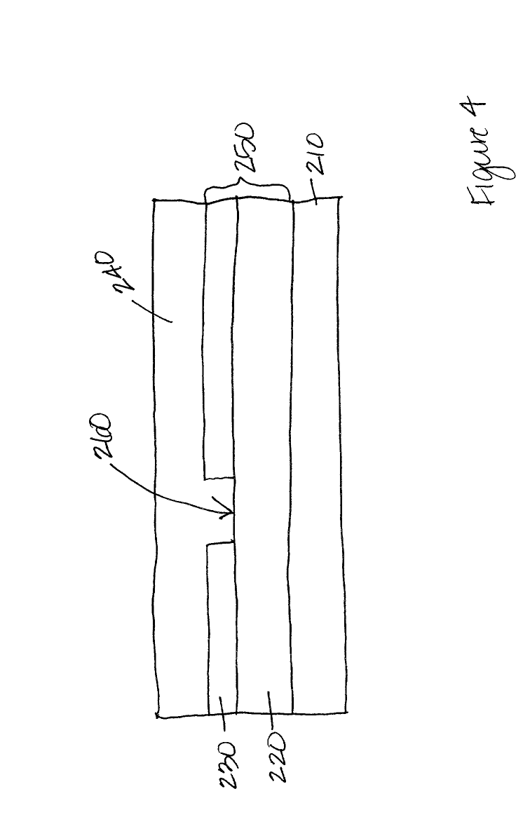

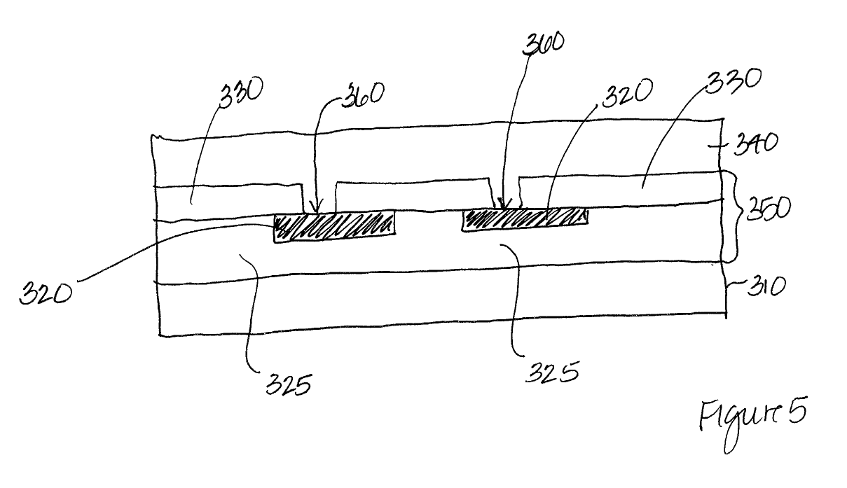

A preferred method of producing a layered material or layered structure that can be reliably tested by an electrical probe both during and after the processing steps is herein described and is shown in FIG. 3. This method generally comprises producing or generating a patterned area or “contact area” on the active material that can directly interface with the electrical probe, testing apparatus, or other testing layer before the next print cycle or before the layered component is finished. Specifically, this method comprises a) providing an active material layer 150; b) forming an active component layer by applying an adhesion promoter layer to the active material layer 160; c) coating the active component layer with a photoresist material 170; d) patterningly exposing a portion of the photoresist material 180; e) removing the unexposed photoresist material from the active component layer to form a bare active component layer comprising the active material and the adhesion promoter layer and a covered active component layer comprising the active material , the adhesion promoter and the photoresist material 185; f) contacting the bare active component layer with a reactive solution, wherein the reactive solution removes the adhesion promoter layer from the bare active component layer 190; and g) removing any remaining photoresist material from the active component layer 195. This previously described preferred method may be used to form the layered component shown in FIGS. 4 and 5.

FIG. 4 shows a layered material or component that comprises a) a substrate layer 210; b) a continuous active component layer 250 that comprises an active material 220 coupled to an adhesion promoter layer 230, wherein the adhesive promoter layer 230 is selectively patterned to expose a contact area 260 on the active material 220; and c) at least one additional layer 240.

FIG. 5 shows a layered material or component that comprises a) a substrate layer 310; b) an non-continuous active component layer 350 that comprises an active material 320 and an insulating material 325 coupled to an adhesion promoter layer 330, wherein the adhesive promoter layer 330 is selectively patterned to expose a contact area 360 on the active material 320; and c) at least one additional layer 340.

Contemplated substrates and substrate layers 210, 310 used herein interchangeably, may comprise any desirable substantially solid material. Particularly desirable substrate layers 10 would comprise films, glass, ceramic, plastic, metal or coated metal, or composite material. In preferred embodiments, the substrate 210; 310 comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimides, BT, and FR4. In more preferred embodiments, the substrate comprises a material common in the packaging and circuit board industries such as silicon, copper, glass, and another polymer.

Substrate layers 210, 310 contemplated herein may also comprise at least two layers of materials. One layer of material comprising the substrate layer may include the substrate materials previously described. Other layers of material comprising the substrate layer may include layers of polymers, monomers, organic compounds, inorganic compounds, organometallic compounds, continuous layers and nanoporous layers.

The substrate layer 210, 310 may also comprise a plurality of voids 145 (shown in FIG. 2) if it is desirable for the material to be nanoporous instead of continuous. Voids 145 are typically spherical, but may alternatively or additionally have any suitable shape, including tubular, lamellar, discoidal, or other shapes. It is also contemplated that voids 145 may have any appropriate diameter. It is further contemplated that at least some of the voids 145 may connect with adjacent voids to create a structure with a significant amount of connected or “open” porosity. The voids 145 preferably have a mean diameter of less than 1 micrometer, and more preferably have a mean diameter of less than 100 nanometers, and still more preferably have a mean diameter of less than 10 nanometers. It is further contemplated that the voids 145 may be uniformly or randomly dispersed within the substrate layer. In a preferred embodiment, the voids 145 are uniformly dispersed within the substrate layer.

Thus, it is contemplated that the substrate layer 210, 310 may comprise a single layer of conventional substrate material. It is alternatively contemplated that the substrate layer may comprise several layers, along with the conventional substrate material, that function to build up part of electronic component.

Suitable materials that can be used in additional substrate layers comprise any material with properties appropriate for a printed circuit board or other electronic component, including pure metals, alloys, metal/metal composites, metal ceramic composites, metal polymer composites, cladding material, laminates, conductive polymers and monomers, as well as other metal composites.

An active material that is similar to the ones previously described herein can be purchased directly from a manufacturer or can be fabricated for the specific component or layered material in house. The active material may comprise that material or combination of materials necessary to produce the active material layer, such as resistor paste, capacitor paste, metals, metal alloys, composite materials, or conductive polymers.

Once the active material is available for use, a continuous layer 220 of this active material can be formed using any suitable layering process, such as spinning the active material on to a surface, dripping or rolling the active material on to a surface, printing the active material on to a surface or manually applying the active material to a surface to form a layer.

The active material may also be embedded into another material (as shown in FIG. 2 and 5), preferably an insulating layer, to form a non-continuous active material layer, similar to those embedded components and methods of production thereof described in U.S. application Ser. No. 09/752660 filed in December of 2000 that is incorporated herein by reference in its entirety.

The second layer or adhesion promoter layer 230, 330 comprises an adhesion promoter, which is important to the production of the layered material, because of the desire and necessity for an optimal and strong bond between the active material, the adhesive material and any additional layers. The adhesion promoter layer 230, 330 may comprise any suitable adhesion promoter depending on the active material and the desired electrical properties. Contemplated adhesion promoters comprise organic materials, preferably those materials that are oxidized, which are known in the art to optimize the adhesive strength between the adhesive and the active material layer. Examples of preferable adhesion promoters are black oxide, white oxide and brown oxide. Black oxide is a controlled coating of a cupric copper oxide that develops long crystals to promote adhesion. White oxide is a treatment process called DURABOND™ developed by DuPont that applies a 0.1 μm coating of tin-tin oxide on the active material surface followed by a silane coupling agent application that forms covalent chemical bonds with both the tin oxide and the laminate resin or adhesive. Brown oxide is similar to black oxide but with shorter crystals.

The contact area 260, 360 can be produced by first coating the active material layer 250, 350 with a photoresist material. The photoresist material can comprise any suitable and readily/commercially available photoresist material, such as high-resolution photoresist materials, highly viscous photoresist materials, thick film photoresist materials, thin film photoresist materials, etc. The photoresist material can be coated or applied to the active material layer 250, 350 by printing the photoresist material on to the layer 250, 350, rolling or dripping the photoresist material on to the layer 250, 350, spinning the photoresist material on to the layer 250, 350, dipping the layer 250, 350 into the photoresist material or any other appropriate means for coating or applying the photoresist material to the layer 250, 350.

The active material layer 250, 350 that is coated with photoresist material is then patterningly exposed to a photon source that can activate the exposed photoresist material. The phrase “patterningly exposed” is used herein to mean that the photoresist material has the light generated from a photon source applied to it in a specific pattern, such as a circle, a square, a circuit pattern, a line pattern or any other suitable pattern. The pattern can be formed by a mask that is placed on the surface of the photoresist material and is designed to block specific areas of the photoresist material from photon contact, formed by a laser source or photon gun, or formed by a patterned photon source, such as a square focused light source.

Any photoresist material that is not exposed to the photon source can then be removed to then expose or “form” a bare active component layer that comprises the active material and the adhesion promoter layer. The bare active component layer is essentially the surface of the active component layer before the application of the photoresist material. Any area of the active component layer that is still covered or coated with exposed photoresist material is herein described as a “covered active component layer”.

The bare active component layer is then washed or placed into contact with a reactive solution that preferably does not chemically react with the remaining photoresist material on the covered active component. The reactive solution, however, chemically and/or physically reacts with the adhesion promoter layer 230, 330 by removing the promoter layer 230, 330 from the underlying active material layer 220, 320 in order to form the contact area 260, 360. The reactive solution preferably comprises an acidic compound, such as sulfuric acid, hydrochloric acid or phosphoric acid.

The remaining photoresist material is then removed from the surface of the active component layer 250, 350 by any suitable removal means, thus exposing the top of the adhesion promoter layer 230, 330.

Additional layers 240, 340 of material may be coupled to or otherwise added onto the active component layer 250, 350 in order to continue building a layered component or printed circuit board. It is contemplated that the additional layers will comprise materials similar to those already described herein, including metals, metal alloys, composite materials, polymers, monomers, organic compounds, inorganic compounds, organometallic compounds, resins, adhesives, pastes, dielectric materials and optical wave-guide materials. It is further contemplated that the additional layer or layers of material may be applied to the active component layer in any manner accepted in the art. However, a preferred method of application is by spinning on the additional layer or layers of material.

Adhesive materials may comprise any suitable adhesive, resin, laminate, bond-ply, polymer, monomer, or pre-preg material. It is contemplated that any bonding materials applied to the layered material will act as a dielectric material once the layered material and/or component is cured. In contemplated embodiments, the bonding materials comprise FR4 epoxy, cyanate esters, polyimides, and glass reinforced compounds. In more preferred embodiments, the bonding materials comprise one of FR4 or cyanate ester.

Contemplated polymers may also comprise a wide range of functional or structural moieties, including aromatic systems, and halogenated groups. Furthermore, appropriate polymers may have many configurations, including a homopolymer, and a heteropolymer. Moreover, alternative polymers may have various forms, such as linear, branched, super-branched, or three-dimensional. The molecular weight of contemplated polymers spans a wide range, typically between 400 Dalton and 400000 Dalton or more.

As used herein, the term “monomer” refers to any chemical compound that is capable of forming a covalent bond with itself or a chemically different compound in a repetitive manner. The repetitive bond formation between monomers may lead to a linear, branched, super-branched, or three-dimensional product. Furthermore, monomers may themselves comprise repetitive building blocks, and when polymerized the polymers formed from such monomers are then termed “blockpolymers”. Monomers may belong to various chemical classes of molecules including organic, organometallic or inorganic molecules. The molecular weight of monomers may vary greatly between about 40 Dalton and 20000 Dalton. However, especially when monomers comprise repetitive building blocks, monomers may have even higher molecular weights. Monomers may also include additional groups, such as groups used for crosslinking.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

A layer of laminating material or cladding material can also be coupled to the substrate layer 210, 310 or the active component layer 250, 350 depending on the specifications required by the component. Laminates are generally considered fiber-reinforced resin dielectric materials. Cladding materials are a subset of laminates that are produced when metals and other materials, such as copper, are incorporated into the laminates. (Harper, Charles A., Electronic Packaging and Interconnection Handbook, Second Edition, McGraw-Hill (New York), 1997.)

Before the layered material is incorporated into a layered component or electronic component, through vias may be drilled into the layered material. Through vias are tiny holes that are drilled directly through the signal layers, the bonding materials and the etched clearance in the reference plane. These through vias can be drilled either with conventional drilling tools, chemicals or with lasers. Through vias are important for the layered components because they are used to interconnect layers, store other conductive materials and provide a foundation for other components in the component.

Although several different materials and preferred combinations have been previously described for the components of the active component layer and the layered material, it should be realized that the composition of the active component layer and the layered material is directly dependent on the needs of the customer, the component or the product.

One of the many advantages to the layered materials, layered components, and methods of production described herein is that the layers can be electrically tested to ensure that all active material values (such as resistance for a resistor layer) are within the customer's or product's specification before committing the layers to a full board layup and to lamination. This ability to electrically test the active material values pre-layup is accomplished through the selective/patterned removal of a portion of the adhesion promoter layer during the print cycle process, as outlined below in the Examples section.

### EXAMPLES

The following Example outlines a print cycle program with the second print cycle being part of a preferred embodiment of the invention.

First Print Operation Steps

a. Chemical Clean of Surface of layer

b. Coat Photoresist material onto layer

c. Develop Photoresist material

d. Add a cupric etch layer

e. Strip photoresist from the layer

f. Apply a pentahydrate dip/rinse to the layer

g. Post etch punch of the layer

h. Optically inspect layer

i. Add Black Oxide material to layer

Second Print Operation Steps

a. Coat photoresist material onto both sides of the layer

b. Expose the 0.010″ clearance area in the center of the resistor pad for the contact area.

c. Develop away unexposed photoresist material.

d. Run layer through conveyorized line while applying a 10% concentration sulfuric acid wash

e. Strip the remaining photoresist material

Third Print Operation Steps

a. Coat photoresist material on to layer

b. Expose with the secondary resistor image

c. Develop the photoresist material

d. Remove the oxide coating with sulfuric acid wash.

e. Perform an alkaline etch of the surface

f. Strip the photoresist material

g. Sample the component for resistance values

h. Post etch punch of the layer

i. Electrical test of resistor values at the layer stage

Thus, specific embodiments and applications of electronic components comprising layered materials have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A layered material for use in an electronic component, comprising:
a substrate layer;
an active component layer that comprises an active material coupled to an adhesion promoter layer, wherein the adhesion promoter layer is selectively patterned to expose a contact area on the active material; and
at least one additional layer.

2. The layered material of claim 1, wherein the substrate layer comprises a silicon-based compound.

3. The layered material of claim 1, wherein the electronic component is a printed circuit board.

4. The layered material of claim 1, wherein the active material comprises a resistor.

5. The layered material of claim 1, wherein the active material comprises a capacitor.

6. The layered material of claim 1, wherein the active material comprises a metal.

7. The layered material of claim 6, wherein the metal is copper or nickel.

8. The layered material of claim 1, wherein the adhesion promoter layer comprises an organic material.

9. The layered material of claim 8, wherein the organic material comprises black oxide.

10. The layered material of claim 1, wherein the at least one additional layer comprises an adhesive.

11. The layered material of claim 1, wherein the at least one additional layer comprises an active component layer.

12. The layered material of claim 1, wherein the at least one additional layer comprises a dielectric material.

13. The layered material of claim 12, wherein the dielectric material is porous.

14. The layered material of claim 12, wherein the dielectric material comprises an organic compound.

15. An electronic component comprising the layered material of claim 1.

16. The electronic component of claim 15, wherein the component is a printed circuit board.

17. An electronic product comprising the layered material of claim 1.

18. A method of producing a layered material for an electronic component, comprising:
providing an active material layer;
forming an active component layer by applying an adhesion promoter layer to the active material layer;
coating the active component layer with a photoresist material;
patterningly exposing a portion of the photoresist material;
removing the unexposed photoresist material from the active component layer to form a bare active component layer comprising the active material and the adhesion promoter layer and a covered active component layer comprising the active material, the adhesion promoter layer and the photoresist material;
contacting the bare active component layer with a reactive solution, wherein the reactive solution removes the adhesion promoter layer from the bare active component layer in order to form the contact area; and
removing any remaining photoresist material from the active component layer.

19. The method of claim 18, wherein providing an active material layer comprises providing a continuous or non-continuous resistor material layer, a capacitor material layer, or a signal layer material layer.

20. The method of claim 18, wherein forming an active component layer comprises spinning on or printing the adhesion promoter layer on to the active material layer.

21. The method of claim 18, wherein pattemingly exposing comprises using a photoresist mask, a laser beam, or a patterned light source.

22. The method of claim 18, wherein the reactive solution comprises an acid.

23. The method of claim 22, wherein the acid is sulfuric acid.

24. The method of claim 18, further comprising the steps of electrically testing layered material by contacting an electrical probe to the contact area.
